(19) United States
(12) Patent Application Publication
(10) Pub. No.: US 2014/0139209 A1
(43) Pub. Date: May 22, 2014

(54) MAGNETIC AUTOMATIC TESTING EQUIPMENT (ATE) MEMORY TESTER

(71) Applicant: QUALCOMM INCORPORATED, San Diego, CA (US)

(72) Inventors: Kangho Lee, San Diego, CA (US); Xiao Lu, San Diego, CA (US); Wah Nam Hsu, San Diego, CA (US); Seung H. Kang, San Diego, CA (US)

(73) Assignee: QUALCOMM INCORPORATED, San Diego, CA (US)

(21) Appl. No.: 13/680,432

(22) Filed: Nov. 19, 2012

(51) Int. Cl. G01R 33/02

(52) U.S. Cl. CPC G01R 33/02
USPC 324/211

(57) ABSTRACT

Several novel features pertain to an automatic testing equipment (ATE) memory tester that includes a load board, a projected-field electromagnet, a positioning mechanism and a memory tester. The load board is for coupling to a die package that includes a magnetoresistive random access memory (MRAM) having several cells, where each cell includes a magnetic tunnel junction (MTJ). The projected-field electromagnet is for applying a portion of a magnetic field across the MRAM. The portion of the magnetic field may be substantially uniform. The positioning mechanism is coupled to the electromagnet and the load board, and is configured to position the electromagnet vertically about (above/below) the die package when the die package is coupled to the load board. The memory tester is coupled to the load board. The memory tester is for testing the MRAM when the substantially uniform portion of the magnetic field is applied across the MRAM.

### CLAIM OF PRIORITY UNDER 35 U.S.C. §119

The present application claims priority to U.S. Provisional Application No. ** entitled “Magnetic Automatic Test Equipment (ATE) Memory Tester Device and Method”, filed **, 2012, which is hereby expressly incorporated by reference herein.

### BACKGROUND

1. Field

Various features relate to a magnetic automatic testing equipment (ATE) memory tester.

2. Background

After a die is manufactured and packaged, it is tested to ensure that there are no defects in the die package. Typically, an automatic testing equipment (ATE) tester is used to perform this test. FIG. 1 illustrates an example of an ATE tester 100 that is used to test a die package. Specifically, FIG. 1 illustrates an ATE tester 100 that is used to test a magnetoresistive random access memory (MRAM) die package. As shown in FIG. 1, the ATE tester 100 includes a memory tester 102, a load board 104, a first magnetic pole 106, and a second magnetic pole 108. A memory die 110 is placed on the load board 104. The memory die 110 is electrically coupled to the load board 104. The first magnetic pole 106 is positioned to the side of the memory die 110. The second magnetic pole 108 is positioned on the other side of the memory die 110. The magnet applies a magnetic field on the memory die 110. The load board 104 is coupled to the memory tester 102. The memory tester 102 performs tests on the memory die 110 that is subject to a magnetic field to examine the magnetic properties of an MRAM cell array and also qualify the memory die 110 for production.

As MRAM technology continues to scale down, the magnitude of magnetic fields to switch MRAM cells tend to increase. However it may be difficult to generate sufficiently strong magnetic fields using the above configuration of an ATE tester. This is because for a given form factor of the magnet, the strength of the magnetic field is limited by the gap between two magnetic poles. When the magnetic poles are positioned to the side of the memory die, the separation between the two magnetic poles can be substantial because the separation is limited by the width (˜5 cm or more) of a socket where the memory die is placed for testing. Although a very large magnet with stronger power supply may be used to compensate for this limitation, the form factor of a magnet may also be limited by the ATE tester. This makes it very difficult to produce a magnetic field that is large/strong enough to properly test the MRAM die fabricated using deeply scaled MRAM technology. This is particularly important when one wants to use a compact magnet to build an ATE tester.

Therefore, there is a need for an improved ATE tester that produces a sufficiently large magnetic field in order to properly test a MRAM die package. Ideally, such a sufficiently large magnetic field will allow the ATE tester to fully characterize the magnetic properties of MRAM die packages.

### SUMMARY

Various apparatus and methods described herein provide an automatic testing equipment (ATE) memory tester.

A first example provides an automatic testing equipment (ATE) memory tester includes a load board, a projected-field electromagnet, a positioning mechanism and a memory tester. The load board is for coupling to a die package that includes a magnetoresistive random access memory (MRAM). The MRAM may include several cells, where each cell includes a magnetic tunnel junction (MTJ). The projected-field electromagnet is for applying a portion of a magnetic field across the MRAM of the die package. The portion of the magnetic field may be substantially uniform. The positioning mechanism is coupled to the electromagnet and the load board. The positioning mechanism is configured to position the electromagnet vertically about (e.g., above/below) the die package when the die package is coupled to the load board. The memory tester is coupled to the load board. The memory tester is for testing the MRAM in the die package when the substantially uniform portion of the magnetic field is applied across the MRAM. In some implementations, the MRAM may be a spin transfer torque MRAM (STT-MRAM).

According to one aspect, the ATE memory tester is for testing a magnetic property of at least some of the cells in the MRAM. The testing of the MRAM may include determining at what magnetic field the cell switches from a first state to a second state and vice versa.

According to another aspect, the positioning mechanism includes a motion controller and a plate, where the plate is coupled to the electromagnet. The motion controller may be for moving the plate such that the electromagnet is positioned vertically about (e.g., above) the die package when the die package is coupled to the load board. The motion controller may include one or more motors to precisely position the magnet on top of an MRAM cell array inside the package.

According to yet another aspect, the ATE memory tester may include several electromagnets, where each particular electromagnet is for applying a particular magnetic field to a particular die package from several die packages coupled to the load board. Each particular die package may include a particular MRAM. The electromagnet is capable/configurable to produce several different magnetic field flux patterns across the MRAM.

According to one aspect, the load board may include at least one socket. Each socket is for coupling to a particular die package. The socket may include a dimension. The dimension of the socket may specify a minimum distance between the electromagnet and the die package when the die package is coupled to the socket.

According to another aspect, the position of the electromagnet allows a magnetic field to be applied along the surface (e.g., in-plane) of the die package or perpendicular to the surface of the die package.

A second example provides an apparatus that includes means for coupling to a die package that includes a magnetoresistive random access memory (MRAM). The apparatus also includes means for applying a portion of a magnetic field across the MRAM of the die package. The MRAM may include several cells, where each cell includes a magnetic tunnel junction (MTJ). The portion of the magnetic field may be substantially uniform. The apparatus further includes means for positioning the electromagnet vertically about (e.g., above/below) the die package. The apparatus includes means for testing the MRAM in the die package when the substantially uniform portion of the magnetic field is applied across the MRAM.

A third example provides a computer readable storage medium that includes one or more instructions for testing a die package having a magnetoresistive random access memory (MRAM). The one or more instructions which when executed by at least one processor, causes the at least one processor to: couple the die package to a load board; position an electromagnet vertically about (e.g., above/below) the die package when the die package is coupled to the load board; apply a portion of a magnetic field across the MRAM of the die package, the portion of the magnetic field may be substantially uniform; and test the MRAM in the die package when the substantially uniform portion of the magnetic field is applied across the MRAM. The MRAM may include several cells, where each cell includes a magnetic tunnel junction (MTJ).

A fourth example provides a method for testing a die package having a magnetoresistive random access memory (MRAM). The method couples the die package to a load board. The method positions an electromagnet vertically about (e.g., above/below) the die package when the die package is coupled to the load board. The method applies a portion of a magnetic field across the MRAM of the die package. The MRAM may include several cells, where each cell includes a magnetic tunnel junction (MTJ). The portion of the magnetic field may be substantially uniform. The method tests the MRAM in the die package when the substantially uniform portion of the magnetic field is applied across the MRAM.

### DRAWINGS

Various features, nature and advantages may become apparent from the detailed description set forth below when taken in conjunction with the drawings in which like reference characters identify correspondingly throughout.

FIG. 1 illustrates a magnetic automatic testing equipment (ATE) memory tester.

FIG. 2 illustrates a magnetoresistive random access memory (MRAM) with cells.

FIG. 3A illustrates a magnetic tunnel junction (MTJ) of a cell.

FIG. 3B illustrates a magnetic tunnel junction (MTJ) under low resistance.

FIG. 3C illustrates a magnetic tunnel junction (MTJ) under high resistance.

FIG. 4 illustrates a magnetic automatic testing equipment (ATE) memory tester for testing a memory die package.

FIG. 5 illustrates a close up view of a socket of a magnetic automatic testing equipment (ATE) memory tester.

FIGS. 6A-D illustrate various magnetic field that may be applied to a memory die package.

FIG. 7 illustrates a top view of a magnetic automatic testing equipment (ATE) memory tester for testing a memory die package.

FIG. 8 illustrates another magnetic automatic testing equipment (ATE) memory tester for testing several memory die packages.

FIG. 9 illustrates a magnet array used in a magnetic automatic testing equipment (ATE) memory tester.

FIG. 10 illustrates a conceptual diagram of components of a memory tester.

FIG. 11 illustrates a flow diagram of a method for testing a magnetoresistive random access memory (MRAM).

FIG. 11 illustrates another flow diagram of a method for testing a magnetoresistive random access memory (MRAM).

FIG. 13 illustrates a diagram that shows when cells of a magnetoresistive random access memory (MRAM) switch states.

FIG. 14 illustrates another diagram that shows when cells of a magnetoresistive random access memory (MRAM) switch states.

FIG. 15 illustrates a flow diagram of a method for testing an die package that includes a magnetoresistive random access memory (MRAM).

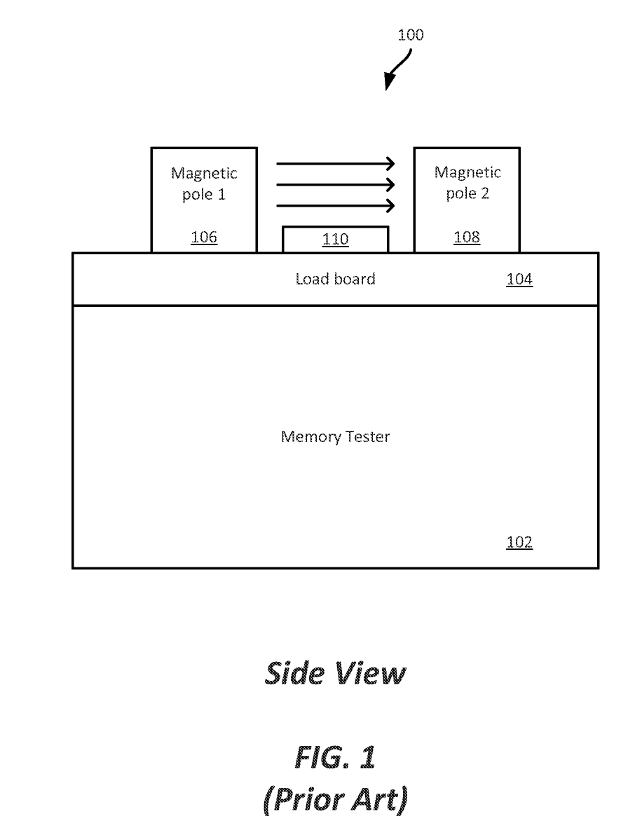

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Several novel features pertain to an automatic testing equipment (ATE) memory tester that includes a load board, a projected-field electromagnet, a positioning mechanism and a memory tester. The load board is for coupling to a die package that includes a magnetoresistive random access memory (MRAM). The MRAM include an array of unit bit cells, where each cell includes a magnetic tunnel junction (MTJ). The projected-field electromagnet is for applying a portion of a magnetic field across the MRAM die package. The portion of the magnetic field may be substantially uniform. The positioning mechanism is coupled to the electromagnet and the load board. In some implementations, the positioning mechanism is configured to position the electromagnet vertically about (e.g., above/below) the die package when the die package is coupled to the load board and precisely move the magnet to the center of the memory cell array. The memory tester is coupled to the load board. The memory tester is for testing the MRAM in the die package when the substantially uniform portion of the magnetic field is applied across the MRAM. In some implementations, the MRAM may be a spin transfer torque MRAM (STT-MRAM).

### Exemplary Magnetoresistive Random Access Memory (MRAM)

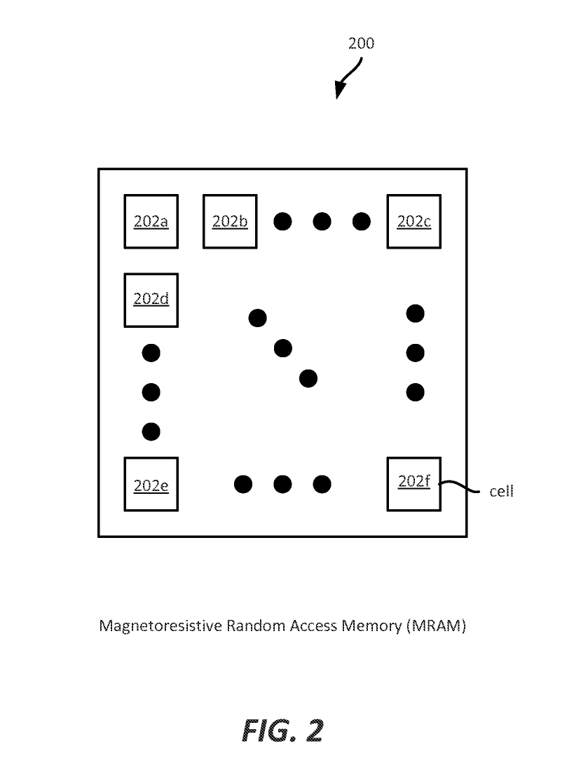

Magnetoresistive random access memory (MRAM) is a memory technology that stores data using magnetic storage elements and/or cells. Each of these cells includes a magnetic tunnel junction (MTJ). The MTJ is what allows the MRAM to store data. FIG. 2 illustrates an example of an MRAM 200 that includes several cells 202a-f. The cells 202a-f are conceptually shown as squares. However, the cells 202a-f may have different shapes, such as rectangular shapes. Each cell 202a-f includes a magnetic tunnel junction (MTJ), which is further described below.

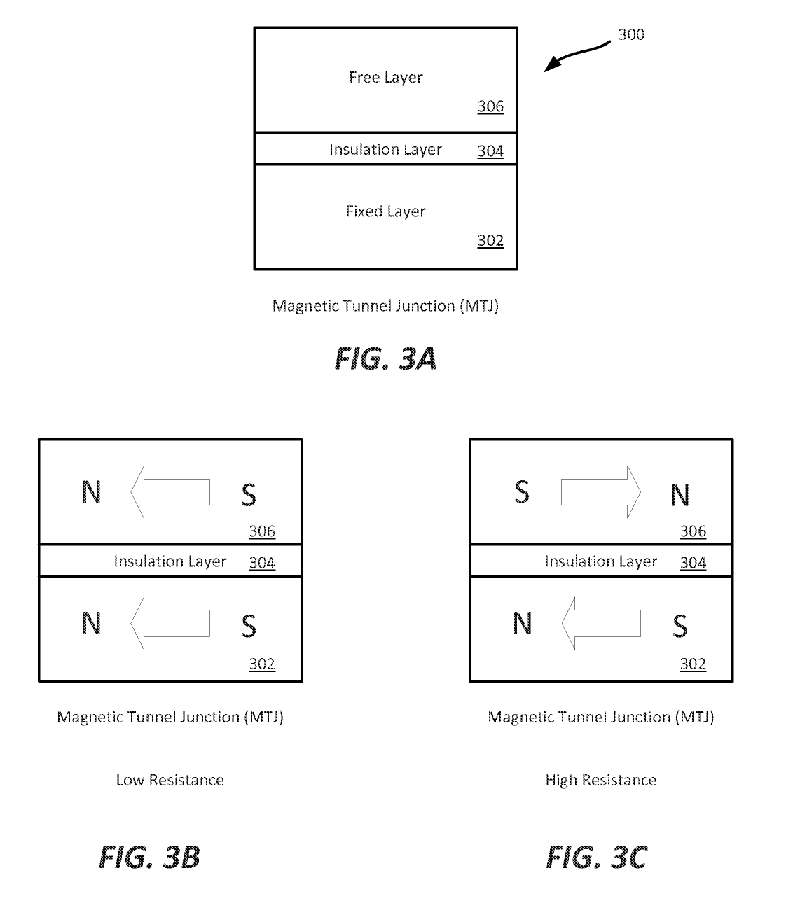

FIG. 3A illustrates a magnetic tunnel junction (MTJ) 300 of at least one of the cells of FIG. 2. As shown in FIG. 3A, the MTJ 300 includes a fixed magnetic layer 302, an insulation layer 304, and a free magnetic layer 306. In some implementations, the magnetic layers 302 and 306 are ferromagnetic layers and the insulation layer 304 is a dielectric layer. Each magnetic layer 302 and 306 has a polarity (a north pole and a south pole). The fixed magnetic layer 302 is fixed because the polarity of the magnetic layer 302 cannot be changed. The free magnetic layer 306 is free because the polarity of the magnetic layer 306 can be changed (the poles can be changed). As mentioned above, the MTJ 300 is what allows the MRAM 200 to store data. The MTJ 300 can have two states. In one state, the free magnetic layer 306 is polarized in the same direction as the fixed magnetic layer 302. In another state, the free magnetic layer 306 is polarized in the opposite direction of the fixed magnetic layer 302.

The insulation layer 304 may be a metal layer in some implementations. In such instances, the MRAM may be referred to as a spin transfer torque (STT) MRAM or STT-RAM.

As described above, the MTJ 300 may be in two possible states, a low resistance state and a high resistance state, which are illustrated in FIGS. 3B and 3C. FIG. 3B illustrates the MTJ 300 in a low resistance state. As shown in FIG. 3B, in a low resistance state, the polarities of magnetic layers 302 and 306 of the MTJ 300 are aligned (the north and south poles of the magnetic layers are on the same side). FIG. 3C illustrates the MTJ 300 in a high resistance state. As shown in FIG. 3C, in a high resistance state, the polarities of the magnetic layers 302 and 306 of the MTJ 300 are opposite to each other (the north pole of the one the magnetic layer is on the opposite side of the north pole of the other magnetic layer).

FIGS. 3B-3C show that the difference between the too states of the MTJ 300 is the polarity of free magnetic layer 306. The difference between the two states of the MTJ 300 may be expressed by the resistance of the MTJ 300 to a current. When the polarities of the two magnetic layers 302 and 306 are aligned, as shown in FIG. 3B, the resistance of the MTJ 300 is low. In contrast, when the polarities of the two magnetic layers 302 and 306 are opposite to each other, the resistance of the MTJ 300 is high (relative to the resistance of the MTJ 300 when the polarities of the magnetic layers are aligned). In other words, the resistance of the MTJ 300 is higher when the polarities of the magnetic layers are opposite to each other then when the polarities of the magnetic layer are aligned. In some implementations, these low and high resistance states may correspond to the binary memory states of 0 and 1.

As mentioned above, the polarity of a free magnetic layer may be switched. In one instance, the polarity of the free magnetic layer is switched by applying a sufficiently large current through the MTJ. Applying a current in the opposite direction through the MTJ will switch the polarity of the free magnetic layer back. In the case of a STT-MRAM, a spin polarized current may be applied to the MTJ to switch the polarity of the free magnetic layer. A spin polarized current is a current that includes electrons that spin in one direction more than in the other direction (more than 50% spin-up or spin-down). A current is typically unpolarized, but can be made a spin polarized current by passing the current through a magnetic layer.

In another instance, applying a sufficiently large magnetic field will also switch the polarity of the free magnetic layer. Similarly, applying a sufficiently large magnetic field in the opposite direction will switch the polarity of the free magnetic layer back. Thus, in addition to current, magnetic field properties must be taken into account when designing and testing MTJs or any memory that uses MTJs, such as an MRAM. Each cell (i.e., each MTJ) of an MRAM may have different properties (e.g., magnetic properties). That is, each cell may switch back and forth between states under different magnetic field strengths.

Having described various properties of an MRAM, an exemplary apparatus and method for testing an MRAM (e.g., package that includes an MRAM) will now be described below.

### Exemplary Magnetic Automatic Test Equipment (ATE) Memory Tester

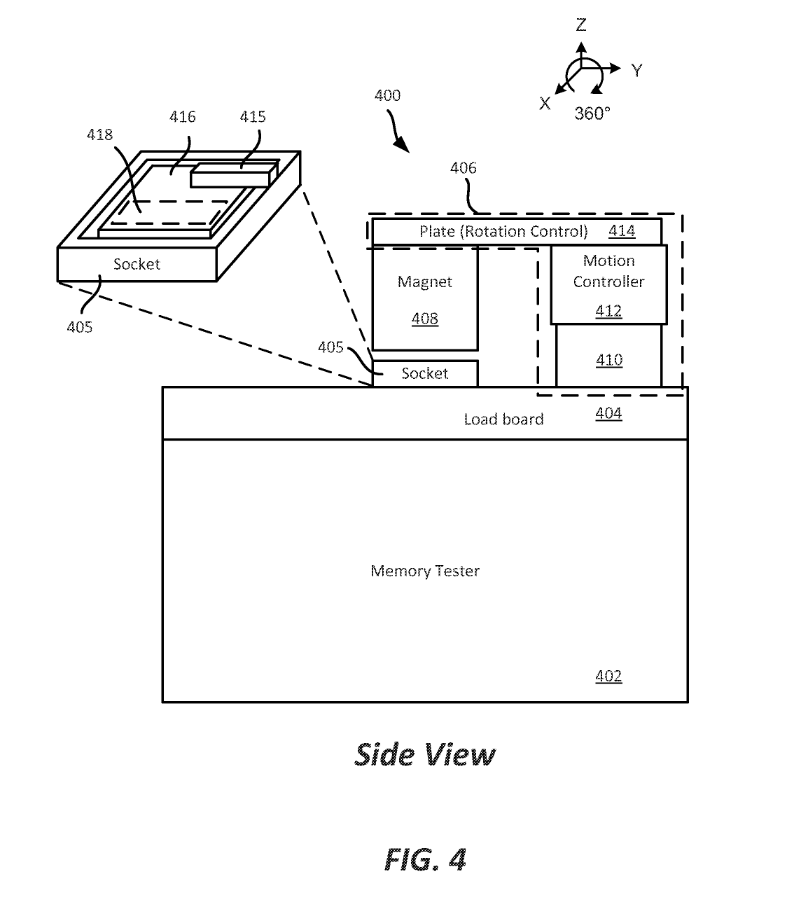

FIG. 4 illustrates an example of an ATE memory tester. Specifically, FIG. 4 illustrates a magnetic ATE tester 400 for testing a die package that includes a magnetoresistive random access memory (MRAM). As shown in FIG. 4, the magnetic ATE tester 400 includes a memory tester 402, a load board 404, a socket 405, a positioning mechanism 406, and a magnet 408.

The positioning mechanism 406 is coupled to the magnet 408. The positioning mechanism 406 allows the magnet 408 to be placed vertically about (e.g., on top, above) of a die package. The positioning mechanism 406 is also coupled to the load board 404 and/or the memory tester 402. The positioning mechanism 406 includes a base 410, a motion controller 412 and a position plate 414. As shown in FIG. 4, the base 410 is coupled to the load board 404. However, in some implementations, the base 510 may be coupled (e.g., directly, partially) to the memory tester 402.

The motion controller 412 is for controlling the position of the magnet 408. In some implementations, the motion controller 412 positions the magnet 408 by rotating the plate 414, which moves the magnet 408 over a die package. In addition, the magnet 408 may be rotated or pivoted about the plate 414 in some implementations. Moreover, the magnet 408 may be capable of laterally and/or longitudinally moving across the plate 414. The use of one or more motors may facilitate the movement and rotation of the plate and/or magnet. Examples of motors include servo motors, stepper motors, and/or hydraulic units. In some implementations, these motors allow the magnet to be precisely positioned above the die packages and/or the MRAM in the die packages.

As further shown in FIG. 4, the socket 405 is coupled (e.g., electrically) to the load board 404. The socket 405 may be for receiving a die package 416 that includes a memory array 418. The memory array may be an MRAM (e.g., STT-MRAM). In some implementations, the socket 405 may receive the die package 416 and hold the die package 416 during testing of the MRAM. The socket 405 may include input/output terminals and/or pins (not shown) which may be coupled to input/output terminals of a die package (e.g., die package 416). For example, the socket 405 may include flip-chip bumps (not shown) that are configured to couple (e.g., receive) to contacts of the die package 416. The flip-chip bumps of the socket 405 may be electrically coupled to the load board 404 and/or memory tester 402.

in some implementations, the socket 405 enables the memory tester 402 to perform testing operations on the memory array 418 (e.g., MRAM) of the die package 416. During testing operations of a die package, the memory tester 402 may monitor the memory array 418 and collect data associated with a state of the memory array 418 (e.g., MRAM). Thus, in some implementations, a die package may simply be placed in the socket 405 and be electrically connected to the load board 404 and/or memory tester 402. This configuration avoids the use of using probes, which is typically used when testing integrated circuit wafers (e.g., memory wafers).

As shown in FIG. 4, the socket 405 may include a socket lid 415 that is configured to secure the die package 416. The socket 405 and the socket lid 415 may be made out of a non-magnetic material. This is done so that the socket 405 and/or socket lid 415 do not affect the magnetic field that is being applied to the die package. In some implementations, the socket lid 415 may be configured to apply pressure to the memory array 418 (and/or die package 416) to secure the memory array 418 (and/or die package 416) in the socket 405 and to couple the contacts of the die package 416 to the flip-chip bumps (not shown). In some implementations, the magnet 408 may apply pressure to the memory array 418 (and/or die package 416) to secure the memory array 418 (and/or die package 416) in the socket 405.

In some implementations, the dimensions (e.g., height) of the socket 405 and/or socket lid 415 may specify the spacing between the magnet 408 and the die package 416 during the testing of the die package 416. In some implementations, the spacing is approximately 4 millimeters (mm) or less. In addition, the socket 405 may also be designed to ensure that the magnet 408 does not touch the die package 416. Specifically, the socket 405 and/or socket lid 415 may act as a barrier to prevent the magnet 408 from applying a three on the die package 416 (which may damage the die package) during testing in some implementations.

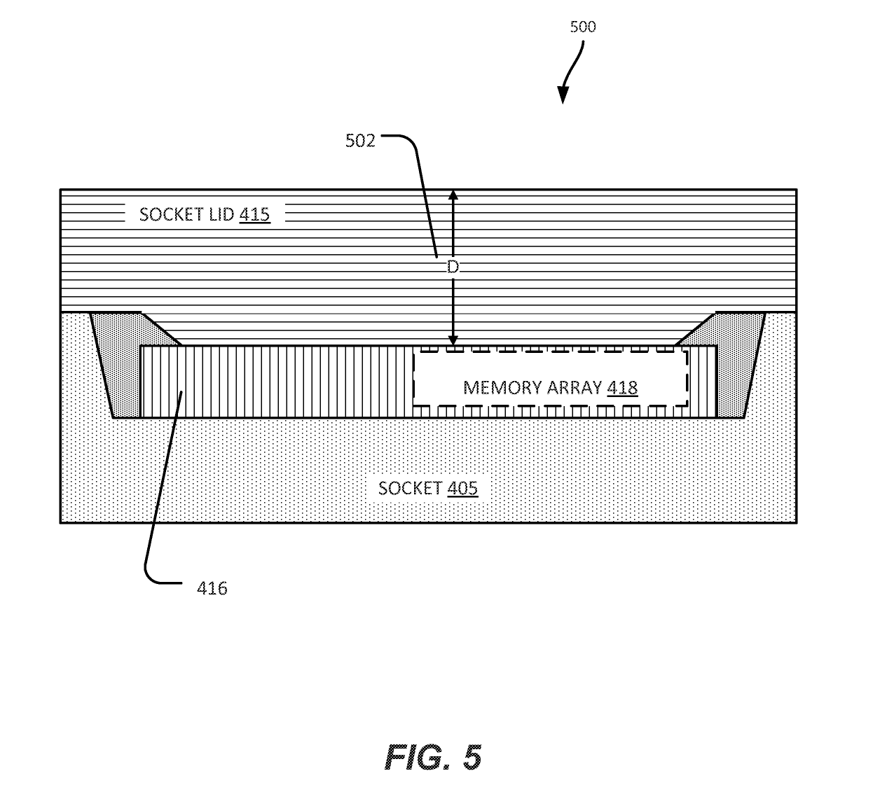

FIG. 5 illustrates a close up view of the socket of FIG. 4. As shown in FIG. 5, the socket 405 includes the socket lid 415. The socket lid 415 may have a height (D) 502. The height (D) 502 may specify the minimum spacing between a die package and a magnet during testing operations. FIG. 5 illustrates the socket 405 being coupled to the die package 416, which includes a memory array 418 (e.g., MRAM). The socket lid 415 is (optionally) placed above the die package 416 to couple and secure the die package 416 to the socket 405 in some implementations. In some implementations, there is no socket lid 415 and a magnet may be positioned over the die package 416 to apply a slight pressure to secure the die package 416 to the socket 405.

In some implementations, the configuration of FIGS. 4-5 allows the magnet 408 to be positioned within millimeters above the die package 416. As a result, a uniform magnetic field (or uniform portion of a magnetic field) having a large magnetic field strength (e.g., 1000 Oersted or more) may be applied to the die package 416 to test for any defective cells within the MRAM, which cannot be done if the magnet 408 was positioned to the side of the die package. The direction of the magnetic field may be along the surface (in-plane) of the die package 516 and/or perpendicular to the surface of the die package 516.

Different implementations may use different magnets. For example, the magnet 408 that is positioned over the die package 416 may be a Helmholtz type magnet or any magnet (e.g., projected-field electromagnet) that may generate uniform magnetic fields. The poles (e.g., north and south poles) of the magnet 408 may be located up and down the magnet (e.g., one pole is near the plate 414, while one pole is near the die package 416 or load board 404). Although, the poles of the magnet 408 may also be located side to side, with the magnet 408 still being placed above the die package 416. Although FIGS. 4-5 illustrate the magnet 408 being positioned above the die package, the magnet 408 may also be positioned below the die package.

In some implementations, the magnet 408 may include an electromagnet (e.g., a compact projected field electromagnet) that generates a magnetic field when the electromagnet is energized. In some implementations, the magnet 408 may be configured to provide a portion of the magnetic field that is substantially uniform and perpendicular to the die package 416 (and/or memory array 418) or in-plane with the die package 416 (and/or memory array 418). The magnet 408 may be positioned so that the die package 416 (and/or memory array 418) is within the substantially uniform portion of the magnetic field.

In some implementations, the substantially uniform portion of the magnetic field is substantially perpendicular to the top and/or bottom surface of the magnet 408. In some implementations, the substantially uniform portion of the magnetic field is substantially in-plane (e.g., parallel) to the top and/or bottom surface of the magnet 408.

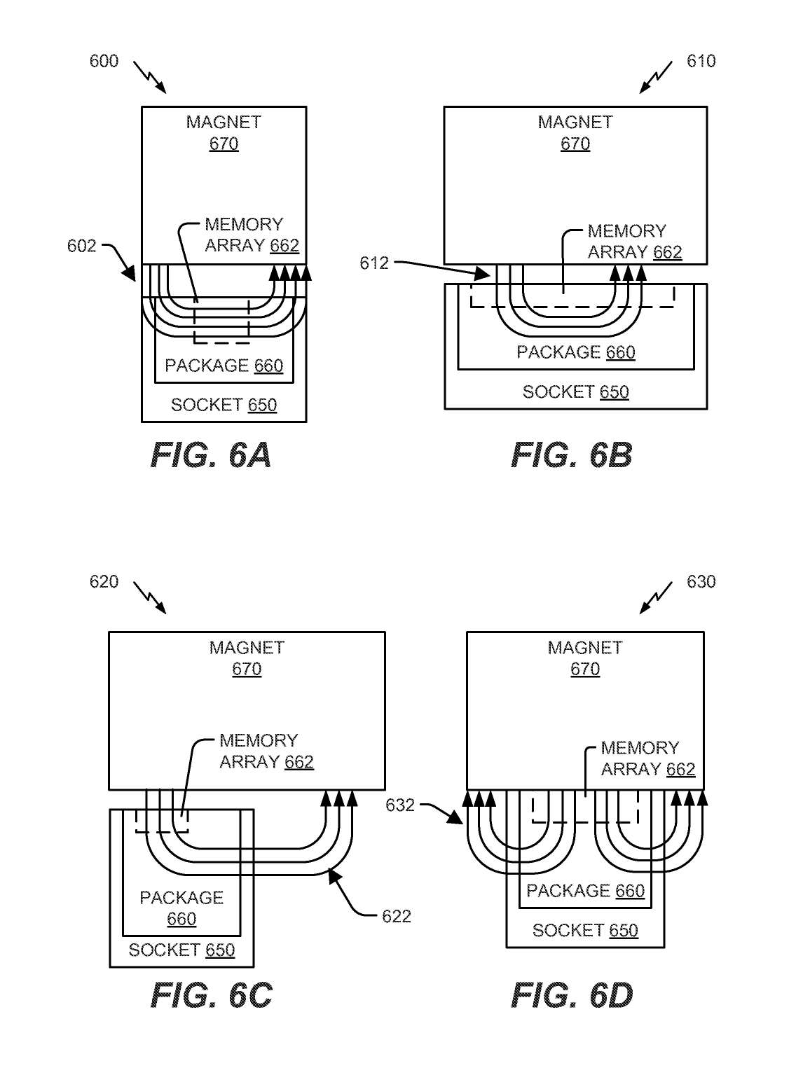

FIGS. 6A-6D illustrate examples of the arrangements of a magnet to generate different types of magnetic fields that may be applied to a die package that includes an MRAM in some implementations.

FIG. 6A illustrates a magnetic arrangement 600 for generating a flux pattern 602 of a magnetic field of a magnet in some implementations. The magnetic arrangement 600 includes a socket 650 and a magnet 670. In some implementations, the socket 650 and the magnet 670 are the socket 405 and the magnet 408, respectively of FIG. 4. As shown in FIG. 6A, the socket 650 includes a die package 660. The die package 660 includes a memory array 662 (e.g., MRAM). The magnetic arrangement 600 is configured to generate a flux pattern 602 for a magnetic field such that a portion of the magnetic field is substantially uniform and in plane to the memory array 662 and the die package 660.

FIG. 6B illustrates another magnetic arrangement for generating a flux pattern 612. As shown in FIG. 6B, the magnetic arrangement 610 is configured to generate a flux pattern 612 for a magnetic field such that a portion of the magnetic field is substantially uniform and perpendicular to the memory array 662. FIG. 6C illustrates another magnetic arrangement 620 that is configured to generate a flux pattern 622 such that a portion of the magnetic field is substantially uniform and perpendicular to the memory array 662. FIG. 6D illustrates yet another magnetic management 630 that is configured to generate a flux pattern 632 such that portion of two magnetic fields are substantially uniform and perpendicular to the memory array 662.

In some implementations, the flux patterns 602, 612, 622, and 632 may be generated based on an arrangement of the poles of the magnet 670. The position of the magnet 670 above or below the memory array 462 may enable 12,000 Oe to be produced and applied to the die package 660 and/or memory array 662 (e.g., MRAM) some implementations. As such, the magnet (e.g., magnet 670) is capable/configurable of producing/generating several different magnetic field flux patterns across an MRAM and/or die package. In some implementations, an MRAM may be subject to several different magnetic field flux patterns. These different magnetic field flux patterns may be applied across the MRAM sequentially in some implementations. The positions of the magnets described may be precisely positioned vertically about (e.g., above/below) the MRAM (e.g., center of MRAM), and/or die package by one or more motors that are part of a positioning mechanism. For example, one or more magnets may be partially, substantially, or entirely positioned above a portion (e.g., center) of the MRAM. One of ordinary skill in the art will appreciate that a strength of the magnetic field applied to the memory array 662 may be determined by a distance (e.g., a spacing) between the magnet 670 and the die package 660 and/or a distance between the magnet 670 and the socket 650.

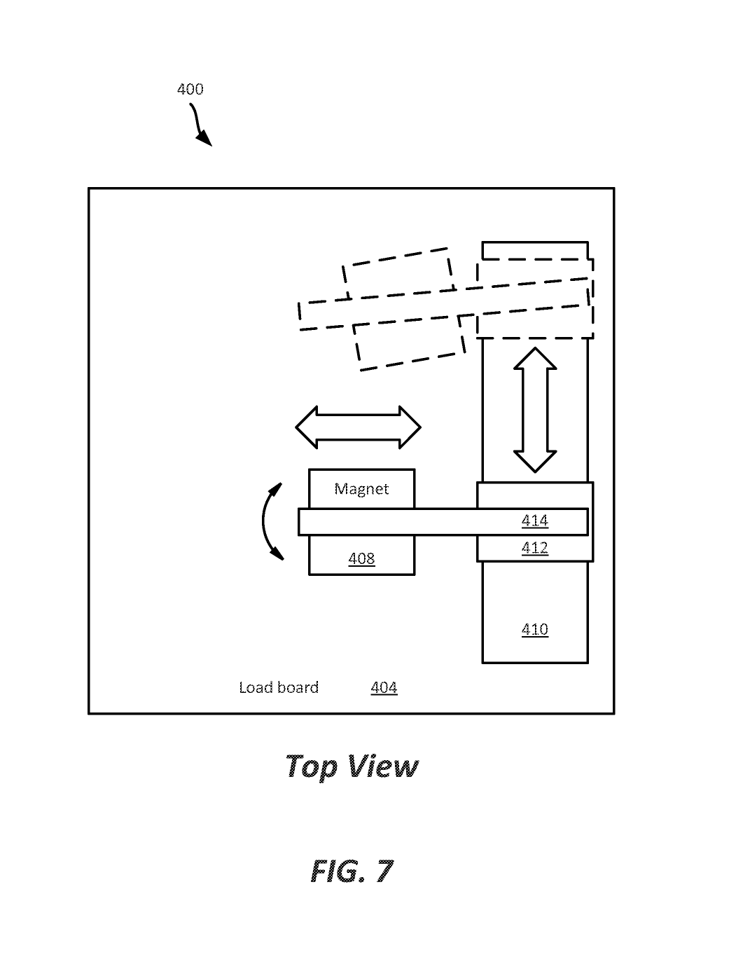

As described above the magnet may be moved to position the magnet above a die package that is going to be tested. Different implementations may move the magnet differently. FIG. 7 illustrates a top view of the ATE tester 400 and the various movements that the positioning mechanism 406 may perform to move the magnet. For example, the motion controller 412 may move along a base 410. In addition, the magnet 408 may move along the plate 414. The magnet 408 may also rotate about the plate 414. Moreover, the plate 414 may rotate about the motion controller 412.

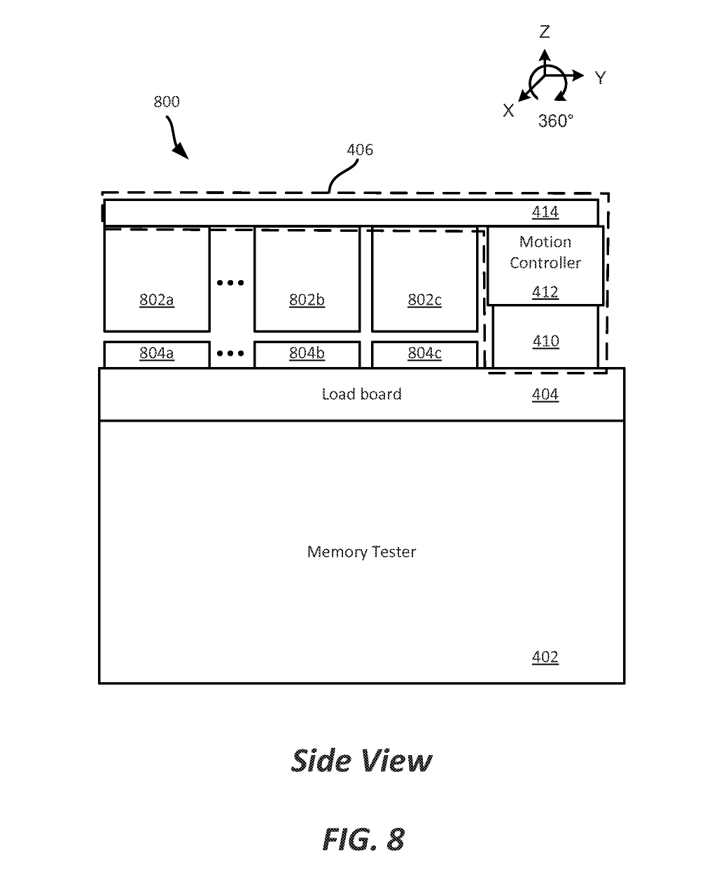

FIG. 8 illustrates another implementation of a magnetic ATE tester. Specifically, FIG. 8 illustrates a magnetic ATE tester 800 with multiple magnets that can test multiple die packages at a time. FIG. 8 is similar to FIG. 4, except that there are multiple magnets 802a-c. The magnets 802a-c may be the magnet described in FIGS. 6A-6D. The magnets 802a-c are positioned to test the die packages, which may be located in sockets 804a-c. In some implementations, the sockets 804a-c may be the socket 405 described in FIGS. 4-5.

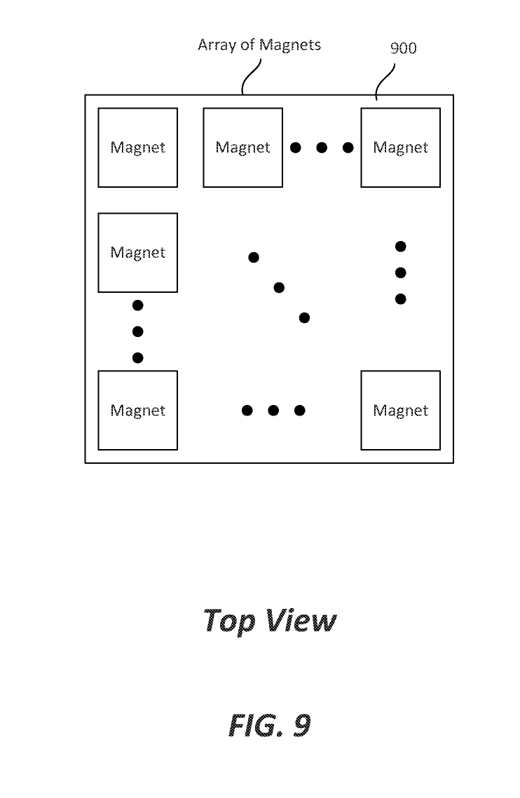

FIG. 9 illustrates another configuration of the magnets that can be used with an ATE memory tester. Specifically, FIG. 9 illustrates a top view of an array of magnets. As shown in FIG. 9, instead of one row or column of magnets, some implementations of an ATE memory tester may have an array of magnets positioned on plate 900. This configuration allows even more die packages to be tested at the same time.

In some implementations, the above described ATE memory tester (which positions magnet above or below MRAM package) uses less power (i.e., has less power requirement) than a memory tester that performs testing operations by positioning a magnet on either side of a memory using a conventional Helmholtz configuration. Moreover, the above described ATE memory tester is capable of generating stronger magnetic fields (e.g., by positioning a field-projecting electromagnet above the MRAM package) than a memory tester that utilizes a conventional Helmholtz configuration (magnets on the side of a memory). Increasing the field strength as compared to a Helmholtz configuration enables the testing of MRAM cells (e.g., STT-MRAM cells) by inducing state changes in the MRAM cells in response to the applied field, which will be further described below with reference to FIGS. 12-14.

Having described the various magnets arrangements, the various components of a memory tester will now be described below.

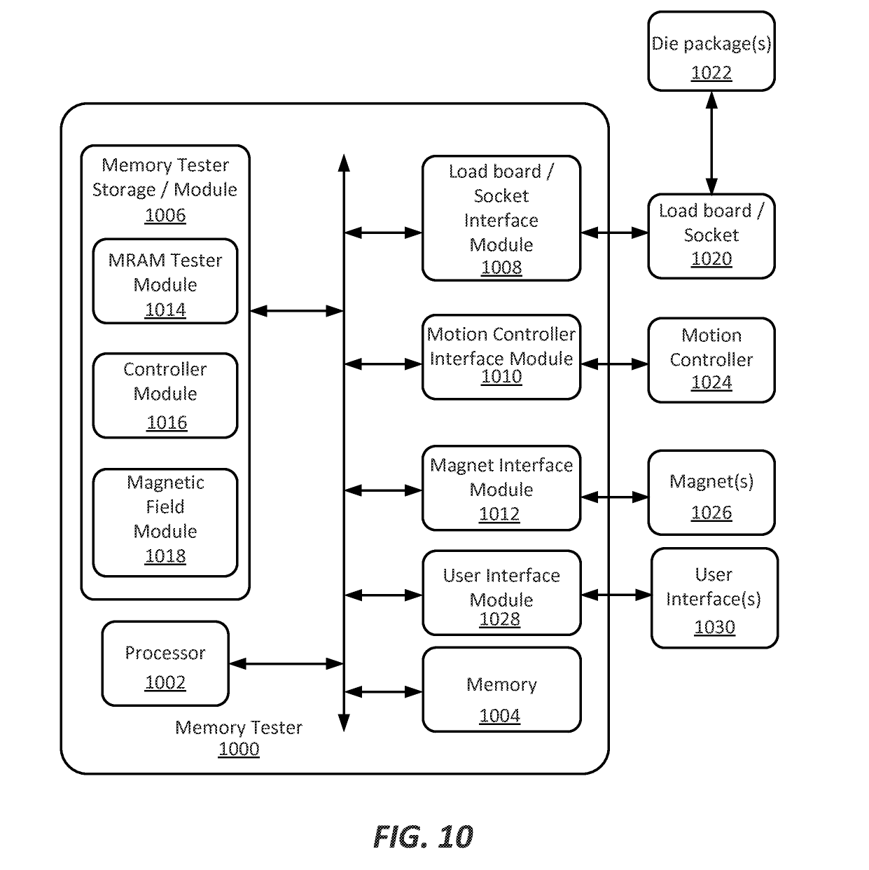

FIG. 10 illustrates a diagram of components of a memory tester 1000 in some implementations. The memory tester 1000 may be any of the memory tester previously described above (e.g., memory tester 402). As shown in FIG. 10, the memory tester 1000 includes a processor 1002, a memory 1004, a memory tester storage/module 1006, a load board/socket interface module 1008, a motion controller interface module 1010, a magnet interface module 1012, a user interface module 828. The memory tester module 1006 includes an MRAM tester module 1014, a controller module 1016, and a magnetic field module 1018.

The memory 1004 may store the memory tester module 1006. However, the memory tester module 1006 may be its own memory device in some implementations. The processor 1002 may execute the memory tester module 1006. In some implementations, the memory tester module 1006 may be part of the processor 1002 or the memory tester module 1006 may be its own processor. The MRAM tester module 1014 is for analyzing data from a die package. For example, the MRAM tester module 1014 may read data received from the load board/socket interface module 1008, which is connected to the load board/socket 1020. The load board/socket 1020 is coupled to one or more die packages 1022. The die package 1022 may include an MRAM (e.g., STT MRAM). The data that is received may be binary bit values (e.g., 0 and 1) of at least some of the cells from the MRAM in the die package. The data that is received may also be raw data (e.g., such as the resistance of the MTJs). The MRAM tester module 1014 may perform analysis of the data to determine whether the die package is defective and if so, which cells are defective.

The controller module 1016 is for controlling the motion controller 1024. The motion controller specifies the movement and/or placement of the magnets 1026 over the die packages. The controller module 1016 communicates with the motion controller 1024 via the motion controller interface module 1010. The motion controller 1024 may include one or more motors to move and place the magnets.

The magnetic field module 1018 communicates with the magnets 1026 (e.g. electromagnets) via the magnet interface module 1012. The magnetic field module 1018 specifies the magnetic field that is to be applied by the magnets 1026 on the die packages 1022. The magnetic field module 1018 may communicate with the MRAM tester module 1014 to indicate the strength of the magnetic field of the magnets. In some implementations, the MRAM tester module 1014 may instruct the magnetic field module 1018 the strength of the magnetic field that is to be applied by the magnets 1026.

The user interface module 828 communicates with user interfaces 830. Examples of user interfaces 830 include keyboard, mouse, display screen and/or any other input/output devices. In some implementations, the user interfaces 830 allow a user to control the testing operations of the die packages, and/or review the data from the testing operations.

Having described the components and configuration of a magnetic ATE memory tester, a method for testing a die package that includes an MRAM will now be described.

Exemplary Method for Testing a Die Package that Includes an MRAM

Before describing a detailed method for testing a magnetoresistive random access memory MRAM), a general overview method for testing an MRAM will first be described.

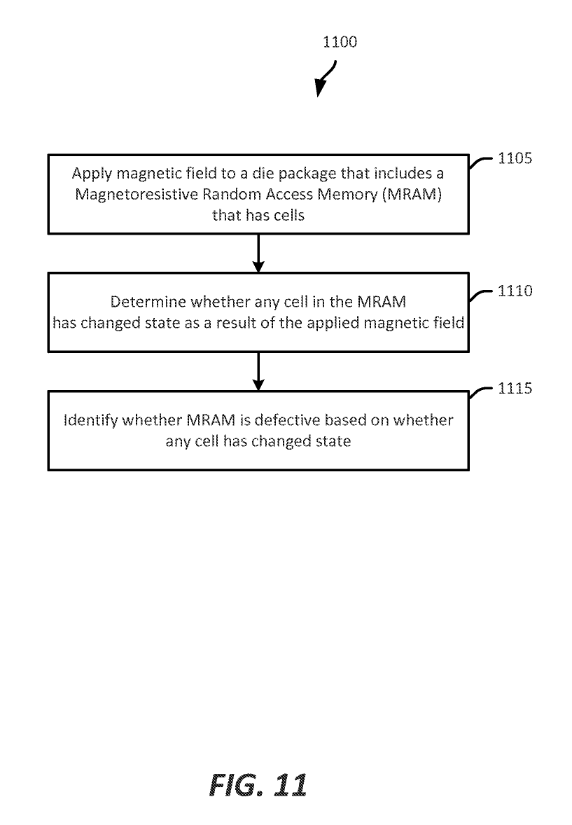

FIG. 11 illustrates a general overview flow diagram of a method for testing a die package that includes an MRAM. The method starts by applying (at 1105) a magnetic field to a die package that includes an MRAM that has cells. The method may apply one magnetic field or the method may apply several magnetic fields of various strengths. The magnetic field may be a positive or negative magnetic field. The magnetic field may be parallel or perpendicular to the surface of the die package and/or MRAM. At least a portion of magnetic field is substantially uniform. The cells may each be a magnetic tunnel junction (MTJ). In some implementations, the MRAM is a spin transfer torque (STT) MRAM.

Next, the method determines (at 1110) whether any cell in the MRAM has changed state as a result of the applied magnetic field. In some implementations, this may include determining whether the bit value of any of the cells (e.g., MTJ) has changed value (e.g., 0 to 1, or 1 to 0).

After determining (at 1110) whether any cell has changed state, the method identifies (at 1115) whether the MRAM is defective based on whether any cell has changed state. Different implementations may use different criterion to identify whether the MRAM is defective. For example, an MRAM may be defective if a number of cells has switched state under a magnetic field strength that is less than a minimum magnetic field strength threshold value. An MRAM may also be defective when a high percentage of cells within a region switches states at a low magnetic field strength.

Having described a general method for testing an MRAM, a more detailed method for testing an MRAM will now be described.

FIG. 12 illustrates a flow diagram of a method for testing an MRAM. The method may be used to test a STT MRAM in some implementations. In some implementations, the method of FIG. 12 may be an iterative loop of steps 1105 and 1110 of FIG. 11.

The method 1200 starts by reading (at 1205) the state of at least some of the cells in the MRAM. In some implementations, this means the method reads (at 1205) the binary value of at least some of the cells (e.g., 0 or 1) in the MRAM. In some implementations, the method may reset (e.g., write) the binary values of some or all the cells to a default value (e.g., 0 or 1). The method applies (at 1210) a magnetic field to the MRAM. The magnetic field is an initial magnetic field and may be positive or negative. At least a portion of the magnetic field is substantially uniform. The method reads (at 1215) at least some of the cells to determine whether the state of the cells has changed (e.g., going from 0 to 1, or 1 to 0) and records any changes. This may include determining whether the resistance of the MTJ of the cell has changed (e.g., lower resistance or higher resistance). Recoding the change may also include recording the strength of the magnetic field that resulted in the change in state.

Next, the method determines (at 1220) whether to increase the magnetic field. If so, the method increases (at 1225) the strength of the magnetic field and proceeds to 1210 to apply the increased magnetic field. Different implementations may perform this determination differently. In some implementations, the magnetic field is increased until a pre-determined magnetic field is reached. In some implementations, the magnetic field is increased until all cells have switched states. In some implementations, several iterations of increasing, applying, reading and recording are performed. When no further increase in the magnetic field is required, the method ends.

In some implementations, the method of FIG. 12 may be repeated on the MRAM, but an opposite (negative) magnetic field is applied instead. That is, after incrementally applying an increasing magnetic field, an opposite and increasing magnetic field is incrementally applied to the MRAM. For example, in the first pass, the magnetic field is increased from 0 to 500 Oersted. In a second pass, the magnetic field is increased from 0 to −500 Oersted. The order of the passes may be reversed as well. That is, a negative magnetic field is first applied followed by a subsequent positive magnetic field.

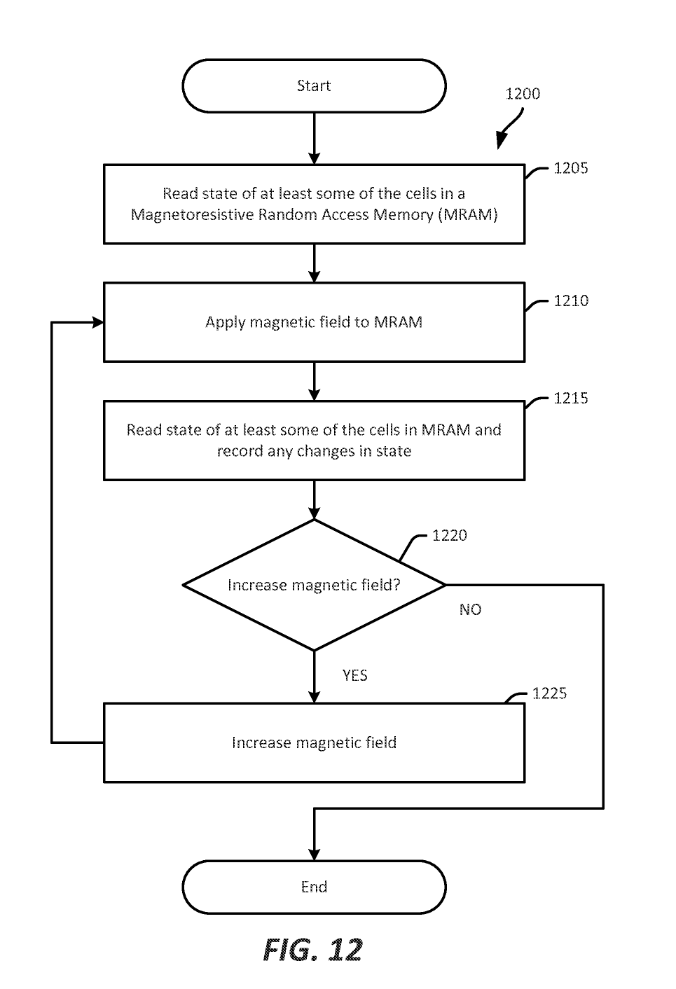

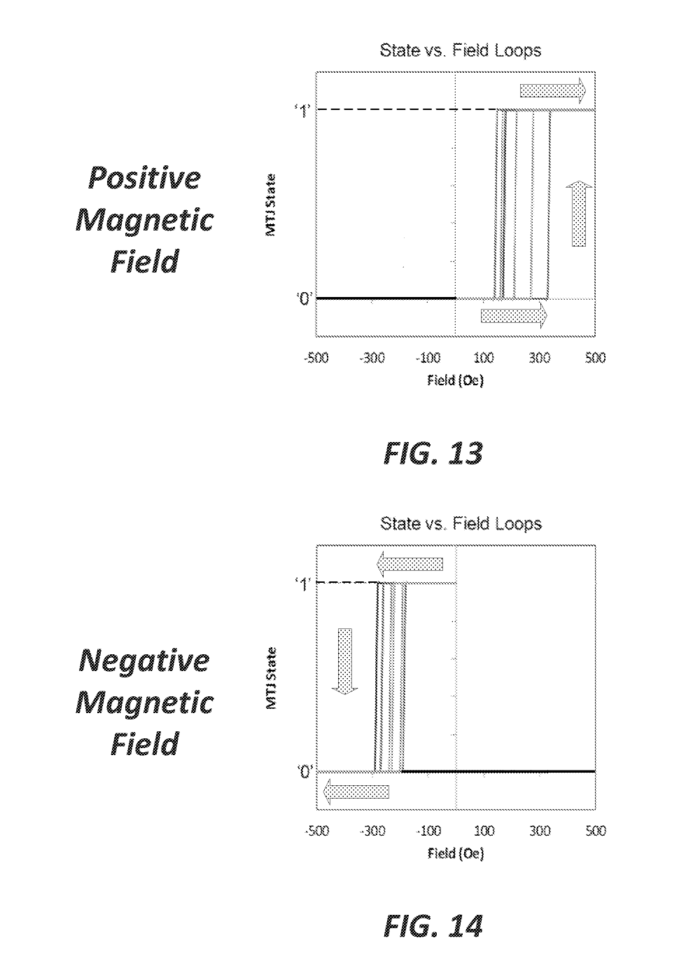

FIGS. 13-14 illustrate charts showing the state vs. magnetic field correlation for several cells of a MRAM. Specifically, FIG. 13 illustrates the positive magnetic field strength at which several cells switch from a 0 to 1 state. In some instances, a cell may switch state in a magnetic field strength as “low” as 100 Oersted and as “high” as 300 Oersted. However, different cells (e.g. MTJs) of the MRAM may switch differently. FIG. 13 shows that as the magnetic field strength increases, more and more cells switch states.

FIG. 14 illustrates the negative magnetic field strength at which several cells switch from a 1 to 0 state. In this example, the magnetic field strength range at which the cells switch states is somewhere between −150 and −300 Oersted. However, different cells (e.g., MTJs) of the MRAM may switch differently. FIG. 14 shows that as the negative magnetic field strength increases, more and more cells switch states.

Once the data for some or all the cells is measured/collected, a distribution of the cells of the MRAM can be analyzed to find issues with the MRAM. For example, if too many cells switch at a low end of the Oersted range (e.g., less than a minimum magnetic field threshold value), then the die package that includes the MRAM may be deemed defective and may be discarded. Moreover, the distribution may be used to analyze if a certain region of an MRAM is consistently producing cells that switch at low Oersted values. This region may be identified, and the problem can be reported back to the manufacturer of the MRAM, so that proper adjustments may be made in order to fix any problems. In some implementations, a die package may still be considered good (i.e., not considered defective) even if some of the cells switch state/values under some magnetic field.

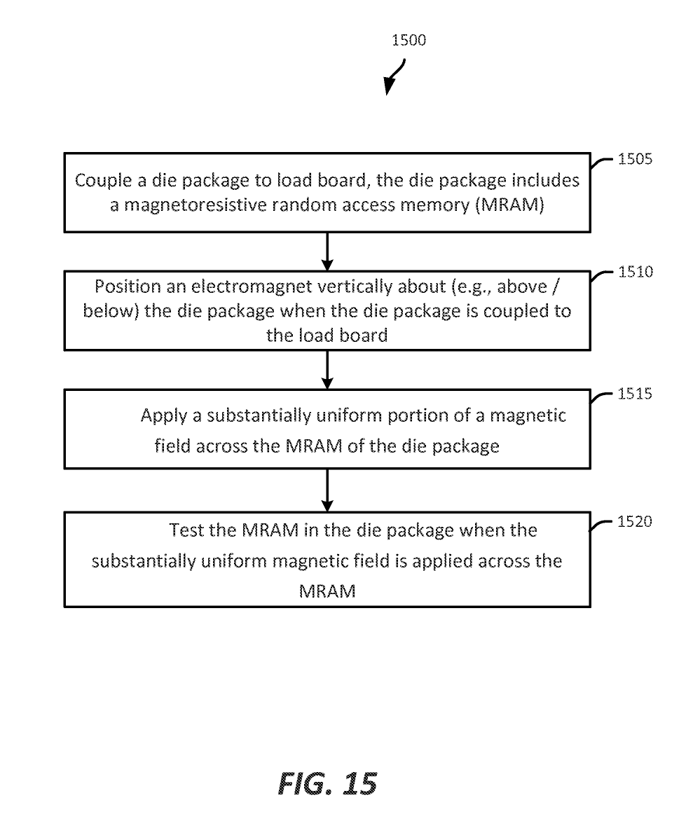

In summary the above described ATE memory tester provides a novel apparatus and method for testing a die package that includes an MRAM. This novel method may be illustrated by FIG. 15.

Specifically, FIG. 15 illustrates a flow diagram of a method for testing a die package that includes an MRAM. As shown in FIG. 15, the method begins by coupling (at 1505) a die package to a load board. The die package includes a magnetoresistive random access memory (MRAM). The MRAM may include a plurality of cells. At least some of the cells are magnetic tunnel junction (MTJ). The MRAM may be a spin transfer torque MRAM (STT-MRAM) in some implementations. In some implementations, coupling (at 1505) the die package to the load board may include coupling the die package to a socket coupled to the load board. Next, the method positions (at 1510) an electromagnet vertically about (e.g., above/below) the die package when the die package is coupled to the load board. In some implementations, positioning (at 1510) the electromagnet may include positioning the electromagnet above/below a socket that includes the die package.

The method then applies (at 1515) a magnetic field across the MRAM of the die package. In some implementations, a portion of the magnetic field that is applied across the MRAM is substantially uniform. The magnetic field may be applied perpendicularly to the surface of the MRAM and/or the magnetic field may be applied parallel (in-plane) to the surface of the MRAM in some implementations. Similarly, the magnetic field may be applied perpendicularly to the surface of the die package and/or the magnetic field may be applied parallel (in-plane) to the surface of the die package in some implementations.

Next, the method tests (at 1520) the MRAM in the die package when the substantially uniform portion of the magnetic field is applied across the MRAM and ends. In some implementations, testing the MRAM includes determining whether at least one of the cells has switched states as a result of the applied magnetic field. Testing the MRAM may also include recording the strength of the magnetic field when a particular cell switches states

One or more of the components, steps, features, and/or functions illustrated in FIGS. 4, 5, 6, 7, 8, 9, 10, 11, 12, 13, 14 and/or 15 may be rearranged and/or combined into a single component, step, feature or function or embodied in several components, steps, or functions. Additional elements, components, steps, and/or functions may also be added without departing from the invention.

One or more of the components, steps, features and/or functions illustrated in the FIGs may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the FIGs may be configured to perform one or more of the methods, features, or steps described in the FIGs. The novel algorithms described herein may also be efficiently implemented in software and/or embedded in hardware.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The term “die package” is used to refer to an integrated circuit wafer that has been encapsulated or packaged or encapsulated.

The term “vertically about” shall refer to a position of an object relative to another object. A first object that is vertically about a second object is a first object that is either above or below the second object. An object that is “vertically about” another object may be partially, substantially, or entirely “vertically about” another object. In some implementations, the term “vertically about” shall refer to a position of an object in the z direction in a x-y-z space. See e.g., FIG. 4. In some implementations, the top and/or bottom surface(s) of a die package may refer to the surface(s) of the die package having the greatest area. In some implementations, the top and/or bottom surface(s) of a die package may refer to the surface(s) of the die package that is coplanar to the surface area of the load board where the die package is coupled to the load board and/or socket.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

Moreover, a storage medium may represent one or more devices for storing data, including read-only memory (ROM), random access memory (RAM), magnetic disk storage mediums, optical storage mediums, flash memory devices and/or other machine readable mediums for storing information. The terms “machine readable medium” or “machine readable storage medium” include, but is not limited to portable or fixed storage devices, optical storage devices, wireless channels and various other mediums capable of storing, containing or carrying instruction(s) and/or data.

Furthermore, embodiments may be implemented by hardware, software, firmware, middleware, microcode, or any combination thereof. When implemented in software, firmware, middleware or microcode, the program code or code segments to perform the necessary tasks may be stored in a machine-readable medium such as a storage medium or other storage(s). A processor may perform the necessary tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

The various illustrative logical blocks, modules, circuits (e.g., processing circuit), elements, and/or components described in connection with the examples disclosed herein may be implemented or performed with a general purpose processor, a digital signal processor (DSP), an application specific integrated circuit (ASIC), a field programmable gate array (FPGA) or other programmable logic component, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing components, e.g., a combination of a DSP and a microprocessor, a number of microprocessors, one or more microprocessors in conjunction with a DSP core, or any other such configuration.

The methods or algorithms described in connection with the examples disclosed herein may be embodied directly in hardware, in a software module executable by a processor, or in a combination of both, in the form of processing unit, programming instructions, or other directions, and may be contained in a single device or distributed across multiple devices. A software module may reside in RAM memory, flash memory, ROM memory, EPROM memory, EEPROM memory, registers, hard disk, a removable disk, a CD-ROM, or any other form of storage medium known in the art. A storage medium may be coupled to the processor such that the processor can read information from, and write information to, the storage medium. In the alternative, the storage medium may be integral to the processor.

Those of skill in the art would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An automatic testing equipment (ATE) memory tester comprising:
a load board for coupling to a die package that includes a magnetoresistive random access memory (MRAM);
a projected-field electromagnet for applying a portion of a magnetic field across the MRAM of the die package, the portion of the magnetic field being substantially uniform;
a positioning mechanism coupled to the electromagnet and the load board, the positioning mechanism configured to position the electromagnet vertically about the die package when the die package is coupled to the load board; and
a memory tester coupled to the load board, the memory tester for testing the MRAM in the die package when the substantially uniform portion of the magnetic field is applied across the MRAM.

2. The ATE memory tester of claim 1, wherein the MRAM includes a plurality of cells, each cell includes a magnetic tunnel junction (MTJ).

3. The ATE memory tester of claim 2, wherein the ATE memory tester is for testing a magnetic property of at least some of the cells in the MRAM.

4. The ATE memory tester of claim 2, wherein testing the MRAM includes determining at what magnetic field the cell switches from a first state to a second state.

5. The ATE memory tester of claim 1, wherein the electromagnet is capable of producing a plurality of magnetic field flux patterns across the MRAM.

6. The ATE memory tester of claim 1, wherein the positioning mechanism is configured to position the electromagnet above or below the die package when the die package is coupled to the load board; and

7. The ATE memory tester of claim 1, wherein the positioning mechanism includes a motion controller and a plate, the plate coupled to the electromagnet.

8. The ATE memory tester of claim 7, wherein the motion controller is for moving the plate such that the electromagnet is positioned vertically about the die package when the die package is coupled to the load board.

9. The ATE memory tester of claim 1, wherein the positioning mechanism is for precisely moving the electromagnet onto a center of an MRAM cell array inside the die package.

10. The ATE memory tester of claim 1, further including a plurality of electromagnets, wherein the electromagnet is from the plurality of electromagnets, each particular electromagnet from the plurality of electromagnets is for applying a particular magnetic field to a particular die package from a plurality of die packages, each particular die package includes a particular MRAM.

11. The ATE memory tester of claim 1, wherein the load board includes a socket, the socket for coupling to the die package, the socket includes a dimension, the dimension of the socket specifying a minimum distance between the electromagnet and the die package when the die package is coupled to the socket.

12. The ATE memory tester of claim 1, wherein the position of the electromagnet allows a magnetic field to be applied along the surface of the die package or perpendicular to the surface of the die package.

13. The ATE memory tester of claim 1, wherein the MRAM is a spin transfer torque MRAM (STT-MRAM).

14. An apparatus comprising:
means for coupling to a die package that includes a magnetoresistive random access memory (MRAM);
means for applying a portion of a magnetic field across the MRAM of the die package, the portion of the magnetic field being substantially uniform;
means for positioning the electromagnet vertically about the die package; and
means for testing the MRAM in the die package when the substantially uniform portion of the magnetic field is applied across the MRAM.

15. The apparatus of claim 14, wherein the MRAM includes a plurality of cells, each cell includes a magnetic tunnel junction (MTJ).

16. The apparatus of claim 15, wherein the means for testing includes a means for testing a magnetic property of at least some of the cells in the MRAM.

17. The apparatus of claim 15, wherein the means for testing the die package includes means for determining at what magnetic field the cell switches from a first state to a second state.

18. The apparatus of claim 14, wherein the means for applying the portion of the magnetic field comprises means for producing a plurality of magnetic field flux patterns across the MRAM.

19. The apparatus of claim 14, wherein the means for coupling includes means for coupling a plurality of die packages, each particular die package includes a particular MRAM.

20. The apparatus of claim 14, wherein the means for positioning includes means for precisely moving the electromagnet onto a center of an MRAM cell array inside the die package.

21. The apparatus of claim 14, wherein the MRAM is a spin transfer torque MRAM (STT-MRAM).

22. A computer readable storage medium comprising one or more instructions for testing a die package comprising a magnetoresistive random access memory (MRAM), which when executed by at least one processor, causes the at least one processor to:
couple the die package to a load board;
position an electromagnet vertically about the die package when the die package is coupled to the load board;
apply a portion of a magnetic field across the MRAM of the die package, the portion of the magnetic field being substantially uniform; and
test the MRAM in the die package when the substantially uniform portion of magnetic field is applied across the MRAM.

23. The computer readable storage medium of claim 22, wherein the MRAM includes a plurality of cells, each cell includes a magnetic tunnel junction (MTJ).

24. The computer readable storage medium of claim 23, wherein the means for testing includes a means for testing a magnetic property of at least some of the cells in the MRAM.

25. The computer readable storage medium of claim 23, wherein the instructions for testing the die package includes instructions for determining at what magnetic field the cell switches from a first state to a second state.

26. The computer readable storage medium of claim 22, wherein the instructions for applying the portion of the magnetic field comprises instructions for producing a plurality of magnetic field flux patterns across the MRAM.

27. The computer readable storage medium of claim 22, wherein the instructions to couple the die package includes instructions to couple a plurality of die packages, each particular die package includes a particular MRAM.

28. The computer readable storage medium of claim 22, wherein the instructions to position the electromagnet includes instructions to precisely move the electromagnet onto a center of an MRAM cell array inside the die package.

29. The computer readable storage medium of claim 22, wherein the MRAM is a spin transfer torque MRAM (STT-MRAM).

30. A method for testing a die package comprising a magnetoresistive random access memory (MRAM), comprising:
coupling the die package to a load board;
positioning an electromagnet vertically about the die package when the die package is coupled to the load board;
applying a portion of a magnetic field across the MRAM of the die package, the portion of the magnetic field being substantially uniform; and
testing the MRAM in the die package when the substantially uniform portion of the magnetic field is applied across the MRAM.

31. The method of claim 30, wherein the MRAM includes a plurality of cells, each cell includes a magnetic tunnel junction (MTJ).

32. The method of claim 31, wherein the means for testing includes a means for testing a magnetic property of at least some of the cells in the MRAM.

33. The method of claim 31, wherein testing the die package includes determining at what magnetic field the cell switches from a first state to a second state.

34. The method of claim 30, wherein applying the portion of the magnetic field comprises producing a plurality of magnetic field flux patterns across the MRAM.

35. The method of claim 30, wherein coupling the die package to the load board includes coupling the die package to a socket that is coupled to the load board.

36. The method of claim 30, wherein coupling the die package includes coupling a plurality of die packages, each particular die package includes a particular MRAM.

37. The method of claim 30, wherein the positioning the electromagnet includes precisely moving the electromagnet onto a center of an MRAM cell array inside the die package.

38. The method of claim 30, wherein the MRAM is a spin transfer torque MRAM (STT-MRAM).

39. The method of claim 30, wherein testing the MRAM comprises:
determining whether at least one cell from the MRAM changes state as a result of the applied magnetic field; and
identifying the die package as being defective when at least one cell from MRAM changes state as a result of the applied magnetic field.

40. The method of claim 39, wherein at least one cell changes state as the result of the applied magnetic field when a bit value stored in the cell changes value.

41. The method of claim 39, wherein the die package is defective when at least one cell from the MRAM changes state as a result of the applied magnetic field that has a magnetic field strength that is less than or equal to a minimum magnetic field strength threshold value.

42. The method of claim 39, wherein applying the portion of the magnetic field comprises sequentially applying a series of magnetic fields having increasing magnetic field strength.

43. The method of claim 42, wherein determining whether at least one cell from the MRAM changes state comprises determining at each magnetic field strength which cell from the MRAM changes states.

44. The method of claim 35, wherein identifying the die package as being defective comprises identifying a distribution of which cell has changed state and under which magnetic field strength did each cell change state under.
